(19) United States
(12) Patent Application Publication
(10) Pub. No.: US 2026/0101525 A1
(43) Pub. Date: Apr. 9, 2026

(54) INDUCTOR IN A BONDED INTEGRATED CIRCUIT ASSEMBLY

(71) Applicant: International Business Machines Corporation, Armonk, NY (US)

(72) Inventors: Nicholas Alexander POLOMOFF, Hopewell Junction, NY (US); Viswas Purohit, East Amherst, NY (US); Kishan Jayanand, Cohoes, NY (US); Erik Milosevic, Schenectady, NY (US); Sarah Nahar Chowdhury, Guilderland, NY (US); Nicholas Latham, Albany, NY (US); Chih-Chao Yang, Glenmont, NY (US)

(21) Appl. No.: 18/909,003

(22) Filed: Oct. 8, 2024

(51) Int. Cl. H01L 23/00; H01L 23/48; H01L 25/00; H01L 25/065

(52) U.S. Cl. CPC H10D 1/20; H10W 20/20; H10W 90/00; H10W 72/944; H10W 80/312; H10W 80/327; H10W 80/743; H10W 90/26; H10W 90/792

(57) ABSTRACT

Embodiments of present invention provide a semiconductor structure. The semiconductor structure includes an inductor, and inductor includes a plurality of semiconductor builds bonded together with one on top of another, each of the plurality of semiconductor builds having two or more through-silicon vias (TSVs) that are vertically aligned with two or more TSVs of an adjacent one of the plurality of semiconductor builds; and a plurality of horizontal bars conductively connecting two of the two or more TSVs of each of the plurality of semiconductor builds, where the two or more TSVs of each of the plurality of semiconductor builds and the plurality of horizontal bars are concatenated together to have a spiral shape, in a vertical plane, that spans across the plurality of semiconductor builds. A method of manufacturing the semiconductor structure is also provided.

### BACKGROUND

The present application relates to manufacturing of semiconductor integrated circuits. More particularly, it relates to structure of an inductor in a bonded integrated circuit assembly and method of manufacturing the same.

As semiconductor industry moves towards smaller node, constraints on available space in semiconductor chips have placed severe limitation on the integration of traditional electronic devices, such as inductors, with semiconductor chips. When being used in integrated circuits, currently existing inductor designs have limitation in achieving high inductance values without occupying substantial chip area. For example, planar inductors generally consume large surface areas while at the same time are limited in performance at high frequencies; ferromagnetic core inductors usually involve complex integration processes and the use thereof may potentially cause interference with other electronic components; embedded inductors are usually limited by the substrate material properties and thus may not be suitable for all types of applications; MEMS inductors require complex and specialized fabrication processes and may also come with high cost and scalability issues; and air-core inductors normally require large dimension or complex structure for achieving high inductance, in addition to having mechanical stability issues.

### SUMMARY

Embodiments of present invention provide a semiconductor structure that includes an inductor in a bonded integrated circuit assembly. The inductor includes a plurality of semiconductor builds bonded together with one on top of another, each of the plurality of semiconductor builds having two or more through-silicon vias (TSVs) that are vertically aligned with two or more TSVs of an adjacent one of the plurality of semiconductor builds; and a plurality of horizontal bars conductively connecting two of the two or more TSVs of each of the plurality of semiconductor builds, where the two or more TSVs of each of the plurality of semiconductor builds and the plurality of horizontal bars are concatenated together to have a spiral shape in a vertical plane and spanning across the plurality of semiconductor builds.

In one embodiment, each of the plurality of semiconductor builds contains a device layer, and the device layer includes a plurality of front-end-of-line devices and a back-end-of-line interconnect structure.

In another embodiment, each of the plurality of semiconductor builds contains at least one dielectric layer at one side of the device layer, and the dielectric layer has at least one of the plurality of horizontal bars embedded therein.

In yet another embodiment, each of the plurality of semiconductor builds contains a passivation layer, the passivation layer directly adjacent to the at least one of the plurality of horizontal bars.

In one embodiment, each of the plurality of semiconductor builds has a thickness ranging from about 10 μm to about 120 μm.

In another embodiment, the spiral shape in the vertical plane is a rectangular spiral shape with a horizontal width ranging from about 1000 μm to about 30000 μm, and a vertical height ranging from about 40 μm to about 800 μm.

According to one embodiment, the semiconductor structure further includes a first contact lead and a second contact lead, the first contact lead being in contact with an outer end of the inductor of the spiral shape.

In one embodiment, the second contact lead is in another vertical plane away from the vertical plane of the spiral shape of the inductor and in contact with an inner end of the spiral shape of the inductor via another horizontal bar.

In one embodiment, there is a pair of bonding layers with at least one set of bonding pads between any two of the plurality of semiconductor builds, and the inductor is bonded to a supporting structure.

Embodiments of present invention further provide a method of forming a semiconductor structure such as an inductor in a bonded integrated circuit assembly. The method includes forming a first semiconductor build with two through-silicon vias (TSVs) embedded therein and a first horizontal bar connecting the two TSVs; forming a second semiconductor build with four TSVs embedded therein and a second horizontal bar connecting two inner TSVs of the four TSVs; and bonding the second semiconductor build to the first semiconductor build with the second horizontal bar facing the first semiconductor build, wherein two outer TSVs of the four TSVs of the second semiconductor build are vertically aligned with and bonded to the two TSVs of the first semiconductor build through two pairs of bonding pads.

According to one embodiment, the method further includes forming one or more additional semiconductor builds that are bonded together and bonded on top of the second semiconductor build, the one or more additional semiconductor builds include two or more TSVs and one or more horizontal bars with each horizontal bar connecting two of the two or more TSVs, wherein the TSVs and the horizontal bars in the first, the second, and the one or more additional semiconductor builds are concatenated together to form an inductor with a spiral shape in a vertical plane.

According to another embodiment, the method further includes forming a first and a second contact lead, the second contact lead having two or more vertically concatenated TSVs formed in another vertical plane away from the vertical plane of the spiral shape of the inductor.

In one embodiment, forming the first semiconductor build includes receiving a first device layer, the first device layer having a plurality of front-end-of-line devices and a back-end-of-line interconnect structure; creating the two TSVs in the first device layer; forming a first dielectric layer on top of the first device layer; and forming the first horizontal bar in the first dielectric layer, the first horizontal bar connecting the two TSVs in the first device layer.

In another embodiment, forming the second semiconductor build includes receiving a second device layer, the second device layer having a plurality of front-end-of-line devices and a back-end-of-line interconnect structure; creating the four TSVs in the second device layer; forming a second dielectric layer on top of the second device layer; and forming the second horizontal bar in the second dielectric layer, the second horizontal bar connecting the two inner TSVs of the four TSVs in the second device layer.

### BRIEF DESCRIPTION OF THE DRAWINGS

The present invention will be understood and appreciated more fully from the following detailed description of embodiments of present invention, taken in conjunction with accompanying drawings of which:

FIG. 1A to FIG. 1Q are demonstrative illustrations of cross-sectional views of a first semiconductor build, in a process of manufacturing thereof, that forms part of an inductor in a bonded integrated circuit assembly according to one embodiment of present invention;

FIG. 2A to FIG. 2S are demonstrative illustrations of cross-sectional views of a second semiconductor build, in a process of manufacturing thereof, and its bonding with the first semiconductor build that together forms part of the inductor in the bonded integrated circuit assembly according to one embodiment of present invention;

FIG. 3A to FIG. 3F are demonstrative illustrations of cross-sectional views of additional semiconductor builds and their bonding with the first and second semiconductor builds, in a process of manufacturing thereof, that forms the inductor in the bonded integrated circuit assembly according to one embodiment of present invention;

FIG. 4 is a demonstrative illustration of cross-sectional view of an inductor in a bonded integrated circuit assembly according to another embodiment of present invention;

FIG. 5 is a demonstrative illustration of cross-sectional view of an inductor in a bonded integrated circuit assembly according to yet another embodiment of present invention;

FIG. 6 is a perspective view of an inductor in a bonded integrated circuit assembly according to a further embodiment of present invention; and

FIG. 7 is a demonstrative illustration of a flow-chart of a method of manufacturing an inductor in a bonded integrated circuit assembly according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

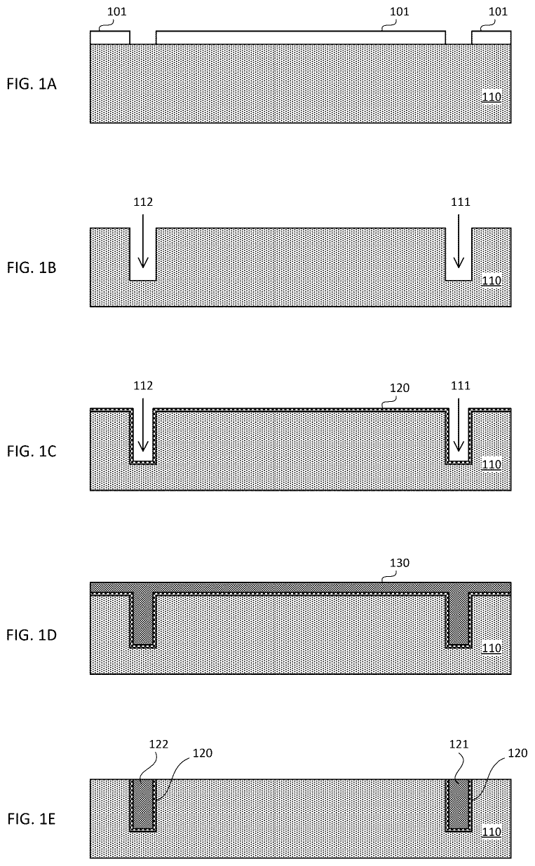

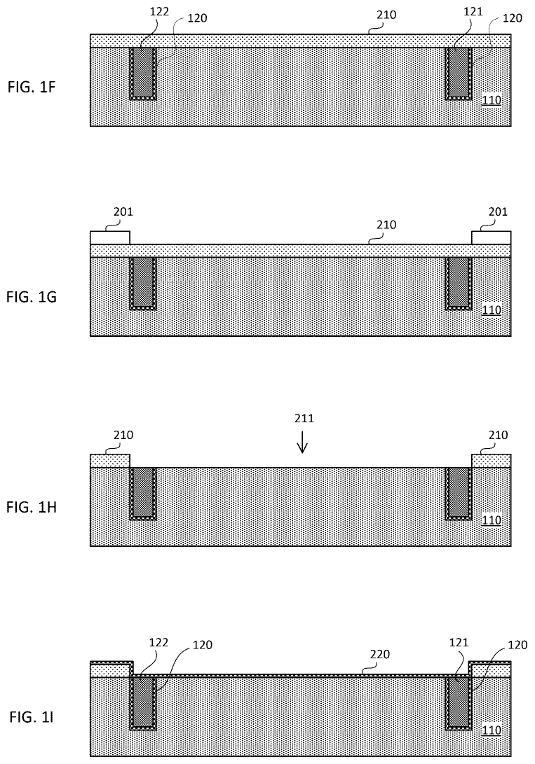

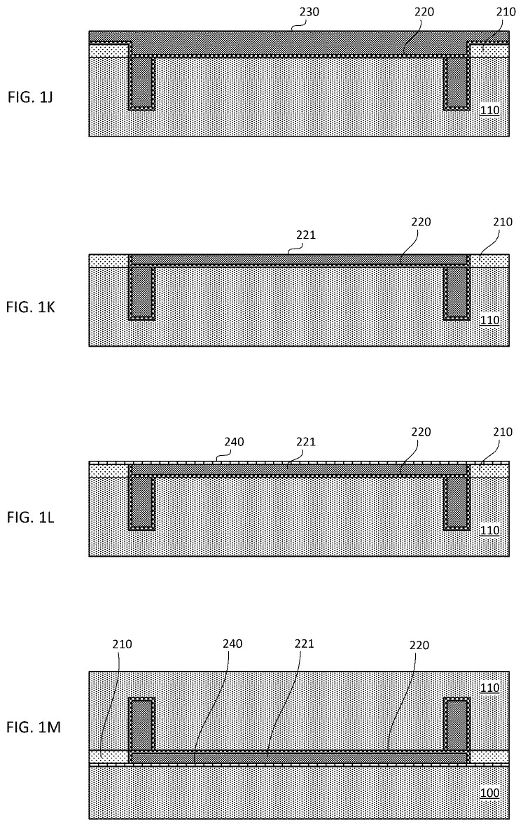

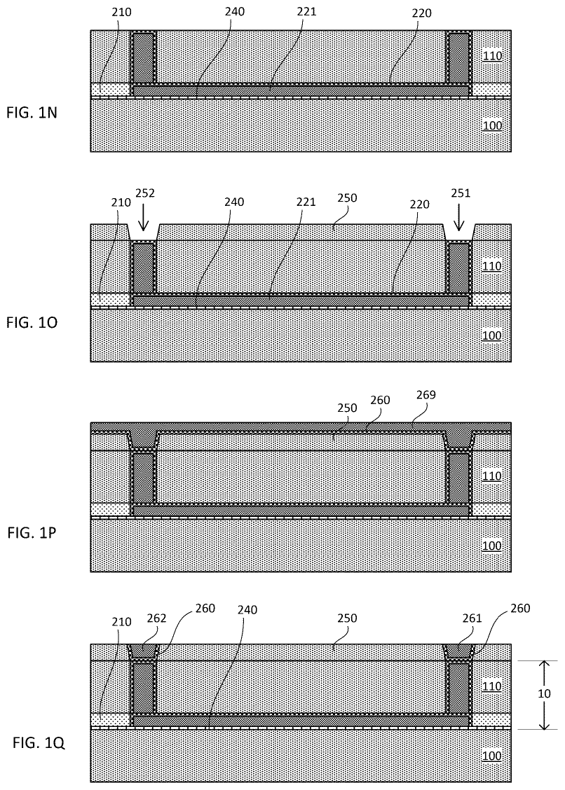

FIG. 1A to FIG. 1Q are demonstrative illustrations of cross-sectional views of a first semiconductor build, in a process of manufacturing thereof, that forms part of an inductor in a bonded integrated circuit assembly according to one embodiment of present invention. More particularly, as is illustrated in FIG. 1A, embodiments of present invention provide receiving or providing a first device layer 110 to form one or more through-silicon vias (TSVs) therein. The first device layer 110 may be a first semiconductor chip or substrate that is manufactured to include a plurality of front-end-of-line (FEOL) devices such as, for example, transistors and/or other active devices as well as a back-end-of-line (BEOL) structure. The BEOL structure, also known as BEOL interconnect structure, may include multiple metal levels of metal lines embedded in multiple dielectric layers, for example, with the metal lines being interconnected by various vias. In most cases, a major portion of the first device layer 110 may be a bulk silicon wafer with stacked dielectric layers that contain the BEOL interconnect structure. The first device layer 110 may initially have a thickness ranging from about 750 μm to about 800 μm, which may be significantly reduced down to about 10 μm to 100 μm later during subsequent processes.

To form one or more TSVs in the first device layer 110, embodiments of present invention provide forming a photomask 101 covering the first device layer 110. The photomask 101 may be formed by depositing a photoresist layer on top of the first device layer 110 and expose the photoresist layer through, for example, a lithographic patterning process to create multiple openings, such as two openings, corresponding to the number of TSVs to be formed in the first device layer 110. Next, as is illustrated in FIG. 1B, embodiments of present invention provide transferring the openings of the photomask 101 onto the first device layer 110 through, for example, a selective etch process to form a first set of openings such as a first and a second opening 111 and 112 in the first device layer 110. After the creation of the first and second openings 111 and 112, the photomask 101 may be removed through, for example, an ash process. Next, as is illustrated in FIG. 1C, embodiments of present invention provide forming a first liner 120 covering the first device layer 110 and lining the first and second openings 111 and 112. The first liner 120 may be a metallic liner of tantalum (Ta), tantalum-nitride (TaN), titanium (Ti), titanium-nitride (TiN), titanium-tungsten (TiW), copper-manganese (CuMn), or other suitable materials. The first liner 120 may be a conformal liner and deposited to have a thickness around 50 nm to 200 nm. The first liner 120 helps form conductive material onto the first device layer 110 in, for example, an electroplating process and improve adhesiveness of the formed conductive material to the first device layer 110.

Next, as is illustrated in FIG. 1D, embodiments of present invention provide performing metallization of the first and second openings 111 and 112 by forming a layer of conductive material 130 such as, for example, copper (Cu) in the first and second openings 111 and 112 through, for example, an electroplating process, a chemical-vapor-deposition (CVD) process, a physical-vapor-deposition (PVD) process, or an atomic-layer-deposition (ALD) process. In the metallization process, the conductive material 130 may also be formed on top of the first device layer 110. After filling the first and second openings 111 and 112 with the conductive material 130, as is illustrated in FIG. 1E, excess portions of the conductive material 130 above the first device layer 110 may be removed through, for example, a chemical-mechanical-polishing (CMP) process, thereby leaving the conductive material 130 in the first and second openings 111 and 112 to form a first set of TSVs such as a first and a second TSV 121 and 122. The first and second TSVs 121 and 122 are thus embedded in the first device layer 110, surrounded at sidewalls and bottoms thereof by the first liner 120.

Next, as is illustrated in FIG. 1F, embodiments of present invention provide forming a first dielectric layer 210 on top of the first device layer 110 to cover the first and second TSVs 121 and 122. The first dielectric layer 210 is formed such that a first horizontal bar may be formed therein to conductively connect the first and second TSVs 121 and 122. In doing so, as is illustrated in FIG. 1G, embodiments of present invention provide forming a photomask 201 on top of the first dielectric layer 210. The photomask 201 may have an opening directly above the first and second TSVs 121 and 122 and the region in-between. Next, as is illustrated in FIG. 1H, embodiments of present invention provide transferring the opening onto the first dielectric layer 210 to create an opening 211 that exposes the first and second TSVs 121 and 122 and the top surface of the first device layer 110 between the first TSV 121 and the second TSV 122. Next, as is illustrated in FIG. 1I, a second liner 220 may be formed on top of the first dielectric layer 210 and lining the opening 211 to cover the exposed first device layer 110, the first and second TSVs 121 and 122 and sidewalls of the opening 211. Like the first liner, 120, the second liner 220 may be a metallic liner of Ta, TaN, Ti, TiN, TiW, CuMn, or other suitable materials and may be conformal to have a thickness around 50 nm to 200 nm.

Next, as is illustrated in FIG. 1J, embodiments of present invention further provide performing metallization of the opening 211 by depositing a layer of conductive material 230 such as, for example, Cu in the opening 211 through an electroplating process, a CVD process, a PVD process, or an ALD process. Next, as is illustrated in FIG. 1K, a CMP process may be applied to remove excess portions of the conductive material 230 on top of the first dielectric layer 210 thereby forming a first horizontal bar 221 embedded in the first dielectric layer 210. The first horizontal bar 221 is surrounded at a bottom and sidewalls thereof by the second liner 220 and conductively connects the first set of TSVs of the first and second TSVs 121 and 122.

Next, as is illustrated in FIG. 1L, embodiments of present invention provide forming a passivation layer 240 on top of the first dielectric layer 210 and covering the first horizontal bar 221. The passivation layer 240 may be a layer of dielectric material, such as silicon-nitride (SiN), and may hermetically seal the first horizontal bar 221 to help prevent, for example, oxidation of the first horizontal bar 221 during subsequent processes of manufacturing the inductor. Next, as is illustrated in FIG. 1M, the first device layer 110 is flipped up-side down, attached to a supporting structure such as thermally bonded to a bulk silicon wafer 100, or a carrier wafer, for processing from backside of the first device layer 110.

Next, as is illustrated in FIG. 1N, embodiments of present invention provide thinning down, for example through a CMP process, the first device layer 110 from a backside thereof until the first and second TSVs 121 and 122 are exposed. The thinned down first device layer 110 may have a thickness ranging from about 10 μm to about 100 μm. After the thinning down, in one embodiment, the first device layer 110 may be further recessed through a selective etch process or a special CMP process to have a top surface thereof slightly below the top surfaces of the first and second TSVs 121 and 122. Thereafter, additional dielectric layers and/or passivation layers may be formed on top of the first device layer 110, subsequently polished and/or recessed down to have the first and second TSVs 121 and 122 exposed or re-exposed. Next, as is illustrated in FIG. 1O, embodiments of present invention provide forming a first bonding layer 250, such as a dielectric layer, on top of the first device layer 110. A first and a second opening 251 and 252 may subsequently be created in the first bonding layer 250 through, for example, a lithographic patterning process. The first and second openings 251 and 252 may be formed to be directly above, thereby expose, the first and second TSVs 121 and 122 in the first device layer 110.

Next, as is illustrated in FIG. 1P, a third liner 260 may be formed on top of the first bonding layer 250 lining the first and second openings 251 and 252 and sidewalls thereof. Like the first liner, 120, the third liner 260 may be a metallic liner of Ta, TaN, Ti, TiN, TiW, CuMn, or other suitable materials and may be conformal to have a thickness around 50 nm to 200 nm. The third liner 260 may thus cover the first and second TSVs 121 and 122. A layer of conductive material 269 such as, for example, Cu may be formed in the first and second openings 251 and 252 and on top of the first bonding layer 250 through, for example, an electroplating process, a CVD process, a PVD process, or an ALD process. Next, as is illustrated in FIG. 1Q, a CMP process may be applied to remove excess portions of the conductive material 269 on top of the first bonding layer 250 thereby forming a first bonding pad 261 and a second bonding pad 262 in the first bonding layer 250. According to one embodiment, the first and second bonding pads 261 and 262 may be slightly recessed, in the range of 1 nm to 10 nm, through a special CMP process for better bonding process and resulting quality.

Hereby, the first semiconductor build 10 is prepared. The first semiconductor build 10 may include the first device layer 110, the first dielectric layer 210, and the passivation layer 240 to have an overall thickness ranging from about 10 μm to about 120 μm. The first semiconductor build 10 may be covered by the bonding layer 250 with the first and second bonding pads 261 and 262 therein; and ready to be hybrid bonded to a second semiconductor build whose manufacturing and process of bonding with the first semiconductor build 10 are described below in more details.

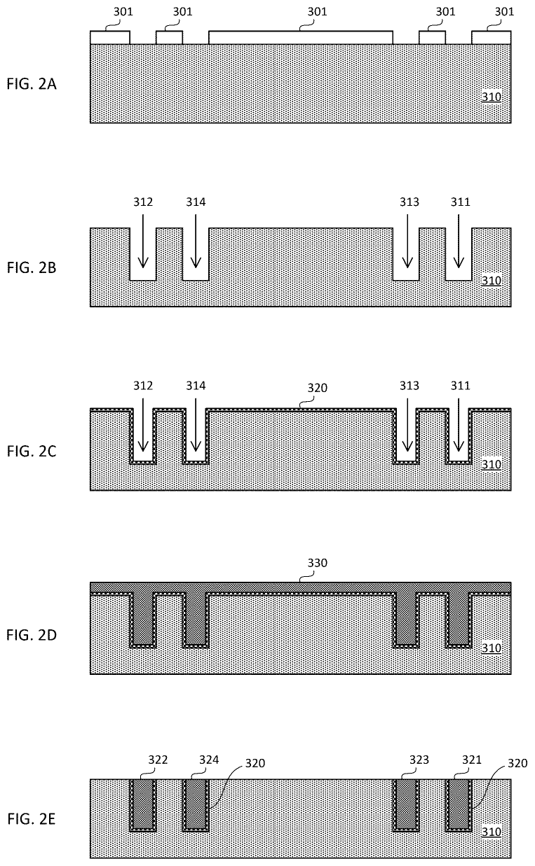

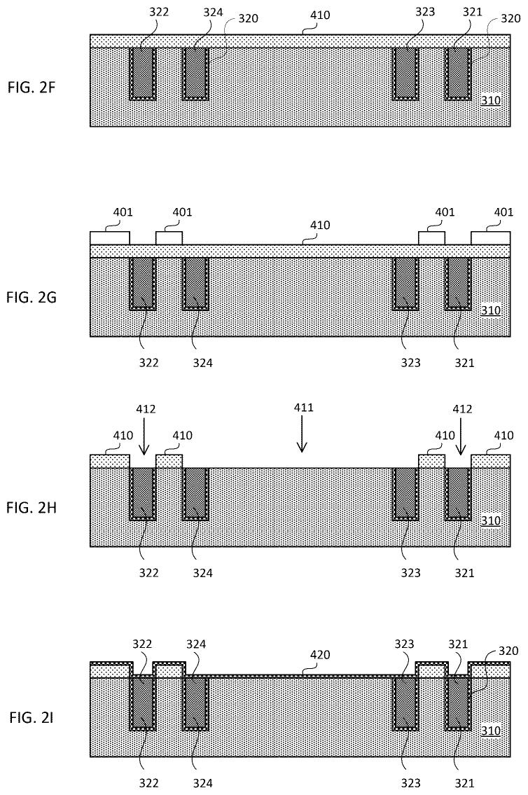

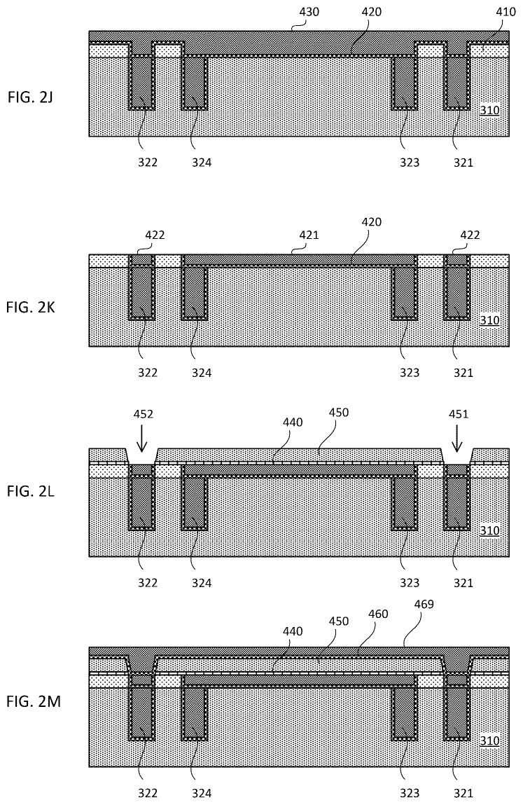

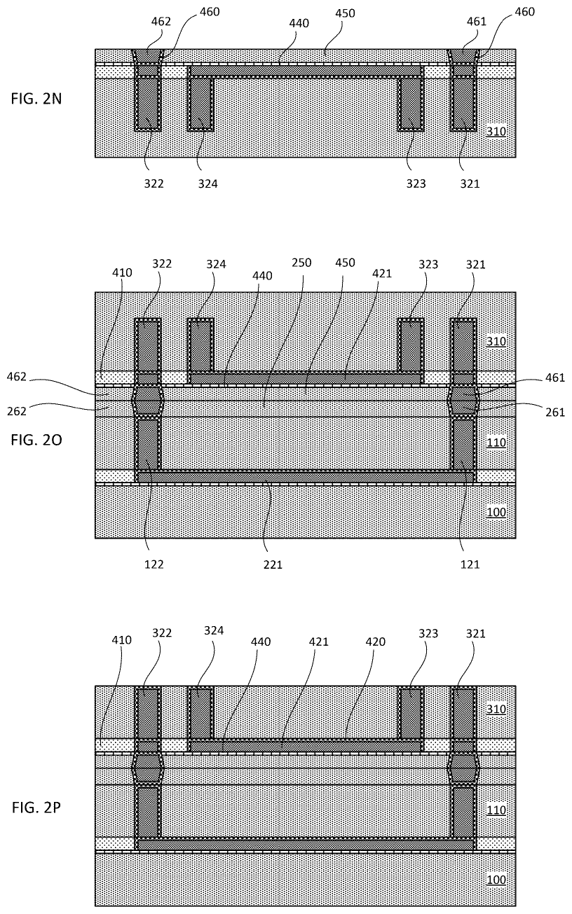

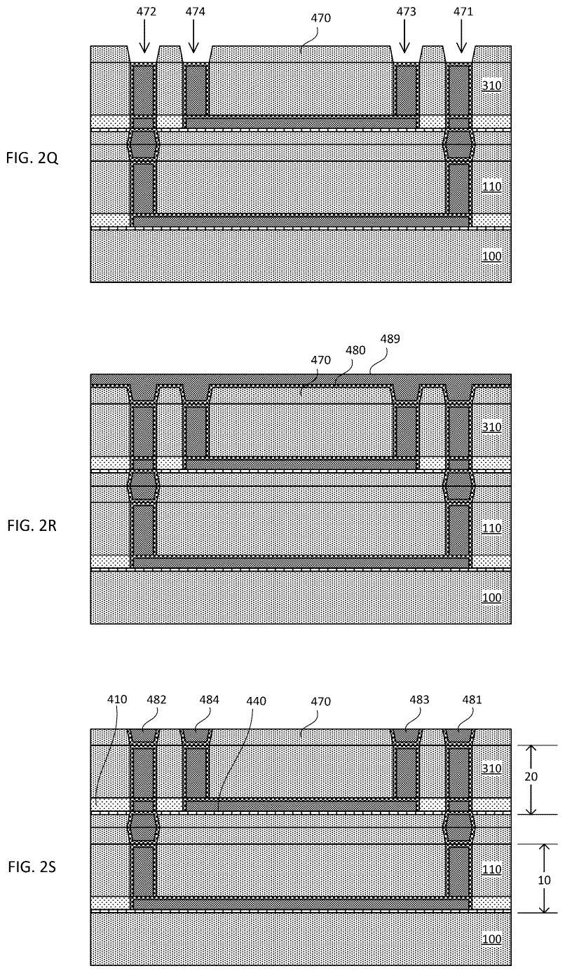

FIG. 2A to FIG. 2S are demonstrative illustrations of cross-sectional views of a second semiconductor build, in a process of manufacturing thereof, and hybrid bonding thereof with the first semiconductor build 10 that forms part of an inductor in a bonded integrated circuit assembly according to one embodiment of present invention. More particularly, as is illustrated in FIG. 2A, embodiments of present invention provide receiving or providing a second device layer 310 to form one or more TSVs therein. Similar to the first device layer 110, the second device layer 310 may be a second semiconductor chip or substrate that is manufactured to include a plurality of FEOL devices and a BEOL interconnect structure. In most cases, a major portion of the second device layer 310 may be a bulk silicon wafer with stacked dielectric layers that contains the BEOL interconnect structure. The second device layer 310 may initially have a thickness ranging from about 750 μm to about 800 μm, which may be significantly reduced down to about 10 μm to 100 μm later during subsequent processes.

To form one or more TSVs in the second device layer 310, embodiments of present invention provide forming a photomask 301 covering the second device layer 310. The photomask 301 may be formed by depositing a photoresist layer on top of the second device layer 310 and expose the photoresist layer through, for example, a lithographic patterning process to create multiple openings, such as four openings, corresponding to the number of TSVs to be formed in the second device layer 310. Next, as is illustrated in FIG. 2B, embodiments of present invention provide transferring the openings of the photomask 301 onto the second device layer 310 through, for example, a selective etch process to form a second set of openings such as a first, a second, a third, and a fourth opening 311, 312, 313, and 314. More particularly, the first and second openings 311 and 312 of the second set of openings may be formed in positions that are separated apart in a same manner as the first and second openings 111 and 112 of the first set of openings in the first device layer 110 such that they may be vertically aligned when being stacked together one on top of another.

After the creation of the first, second, third, and fourth openings 311, 312, 313, and 314 in the second device layer 310, the photomask 301 may be removed through, for example, an ash process. Next, as is illustrated in FIG. 2C, embodiments of present invention provide forming a first liner 320 of the second semiconductor build covering the second device layer 310 and lining the first, second, third, and fourth openings 311, 312, 313, and 314. The first liner 320 may be a metallic liner of Ta, TaN, Ti, TiN, TiW, CuMn, or other suitable materials, and may be conformal to have a thickness around 50 nm to 200 nm. Like the first liner 120, the first liner 320 helps form conductive material onto the second device layer 310 in an electroplate process and improve adhesiveness of the formed conductive material to the second device layer 310.

Next, as is illustrated in FIG. 2D, embodiments of present invention provide performing metallization of the first, second, third, and fourth openings 311, 312, 313, and 314 by forming a layer of conductive material 330 such as, for example, Cu in the first, second, third, and fourth openings 311, 312, 313, and 314 through, for example, an electroplate process, a CVD process, a PVD process, or an ALD process. During the metallization process, the conductive material 330 may also be formed on top of the second device layer 310. Next, as is illustrated in FIG. 2E, excess portions of the conductive material 330 above the second device layer 310 may be removed through, for example, a CMP process, thereby leaving the conductive material 330 in the first, second, third, and fourth openings 311, 312, 313, and 314 to form a second set of TSVs such as two outer TSVs of a first TSV 321 and a second TSV 322 and two inner TSVs of a third TSV 323 and a fourth TSV 324. Both the two outer TSVs, i.e., the first and second TSVs 321 and 322, and the two inner TSVs, i.e., the third and fourth TSVs 323 and 324, are all embedded in the second device layer 310, surrounded at sidewalls and bottoms thereof by the first liner 320.

Next, as is illustrated in FIG. 2F, embodiments of present invention provide forming a second dielectric layer 410 on top of the second device layer 310 and covering the first, second, third, and fourth TSVs 321, 322, 323, and 324. The second dielectric layer 410 may be formed such that a second horizontal bar may be formed therein to conductively connect the third TSV 323 and the fourth TSV 324. Conductive studs may also be formed to help extend the first and second TSVs 321 and 322 upwardly through the second dielectric layer 410. In doing so, as is illustrated in FIG. 2G, embodiments of present invention provide forming a photomask 401 on top of the second dielectric layer 410. The photomask 401 may have multiple openings directly above the first, second, third and fourth TSVs 321, 322, 323, and 324 and above the region between the third and fourth TSVs 323 and 324.

Next, as is illustrated in FIG. 2H, embodiments of present invention provide transferring the multiple openings onto the second dielectric layer 410 to create an opening 411 that exposes the third and fourth TSVs 323 and 324 and top surface of the second device layer 310 between the third TSV 323 and the fourth TSV 324. Additional openings 412 may be created in the second dielectric layer 410 that expose top surfaces of the first and second TSVs 321 and 322. Next, as is illustrated in FIG. 2I, a second liner 420 of the second semiconductor build may be formed on top of the second dielectric layer 410 and lining the opening 411 to cover the exposed second device layer 310, the third and fourth TSVs 323 and 324, and sidewalls of the opening 411. The second liner 420 may also cover the top surfaces of the first and second TSVs 321 and 322 by lining the openings 412. The second liner 420 may be a metallic liner of Ta, TaN, Ti, TiN, TiW, CuMn, or other suitable materials, and may be conformal to have a thickness around 50 nm to 200 nm.

Next, as is illustrated in FIG. 2J, embodiments of present invention provide performing metallization of the openings 411 and 412 by depositing a layer of conductive material 430 such as, for example, Cu in the openings 411 and 412 through, for example, an electroplating process, a CVD process, a PVD process, or an ALD process. Next, as is illustrated in FIG. 2K, a CMP process may be applied to remove excess portions of the conductive material 430 on top of the second dielectric layer 410 thereby forming a second horizontal bar 421 embedded in the second dielectric layer 410. The second horizontal bar 421 is surrounded at a bottom and sidewalls thereof by the second liner 420 and conductively connects the two inner TSVs of the third and fourth TSVs 323 and 324. Conductive studs 422 may also be formed on top of the first and second TSVs 321 and 322, which extend the first and second TSVs 321 and 322 through the second dielectric layer 410.

Next, as is illustrated in FIG. 2L, embodiments of present invention provide forming a passivation layer 440, such as a layer of SiN, on top of the second dielectric layer 410 and depositing a second bonding layer 450, such as a dielectric layer, on top of the second dielectric layer 410 via the passivation layer 440. A first and a second opening 451 and 452 may subsequently be created in the second bonding layer 450, through a lithographic patterning process. The first and second openings 451 and 452 may be formed to be directly above, thereby expose, the conductive studs 422 above the first and second TSVs 321 and 322 in the second device layer 310.

Next, as is illustrated in FIG. 2M, a third liner 460 of the second semiconductor build may be formed on top of the second bonding layer 450 and lining the first and second openings 451 and 452 to cover the first and second TSVs 321 and 322 and sidewalls of the first and second openings 451 and 452. The third liner 460 may be a metallic liner of Ta, TaN, Ti, TiN, TiW, CuMn, or other suitable materials, and may be conformal to have a thickness around 50 nm to 200 nm. A layer of conductive material 469 such as, for example, Cu may be deposited in the first and second openings 451 and 452 and on top of the second bonding layer 450 through, for example, an electroplating process, a CVD process, a PVD process, or an ALD process. Next, as is illustrated in FIG. 2N, a CMP process may be applied to remove excess portions of the conductive material 469 on top of the second bonding layer 450 thereby forming a first and a second bonding pad 461 and 462 in the second bonding layer 450. In one embodiment, the first and second bonding pads 461 and 462 may be slightly recessed, in the range of 1 nm to 10 nm, through a special CMP process for better bonding process and resulting quality.

Next, as is illustrated in FIG. 2O, embodiments of present invention provide flipping the second device layer 310 up-side down and bonding the second dielectric layer 410 to the first semiconductor build 10. For example, the second dielectric layer 410 may be bonded to the first semiconductor build 10 through a hybrid bonding process, with the second horizontal bar 421 facing the first semiconductor build 10, via a pair of bonding layers such as the first bonding layer 250 and the second bonding layer 450. When bonding the second dielectric layer 410 and the second device layer 310 with the first semiconductor build 10, the two outer TSVs of the first and second TSVs 321 and 322 in the second device layer 310 may be vertically aligned, respectively and substantially, with the first and second TSVs 121 and 122 in the first device layer 110 of the first semiconductor build 10. For example, the first TSVs 121 and 321 may be vertically aligned and bonded together via a first set of bonding pads 261 and 461, and the second TSVs 122 and 322 may be vertically aligned and bonded together via a second set of bonding pads 262 and 462. In other words, the first and second TSVs 321 and 322 in the second device layer 310, the first and second TSVs 121 and 122 in the first device layer 110 of the first semiconductor build 10 and the first horizontal bar 221 in the first dielectric layer 210 of the first semiconductor build 10 may be concatenated together as a part of forming an inductor in a bonded integrated circuit assembly.

Next, as is illustrated in FIG. 2P, embodiments of present invention provide thinning down, for example through a CMP process, the second device layer 310 from a backside thereof until top surfaces of the first, second, third, and fourth TSVs 321, 322, 323, and 324 are exposed. In one embodiment, the second device layer 310 may be further recessed through a selective etch process or a special CMP process to have the top surface thereof slightly below the top surfaces of the first, second, third, and fourth TSVs 321, 322, 323, and 324. Additional dielectric layers and/or passivation layers may be formed on top of the second device layer 310, subsequently polished and/or recessed down to have the first, second, third, and fourth TSVs 321, 322, 323, and 324 exposed or re-exposed.

Next, as is illustrated in FIG. 2Q, embodiments of present invention provide forming a first bonding layer 470 on top of the second device layer 310. A first, a second, a third, and a fourth opening 471, 472, 473, and 474 may subsequently be created in the first bonding layer 470 through a lithographic patterning process. The first and second openings 471 and 472 may be formed to be directly above, thereby expose, the first and second TSVs 321 and 322 in the second device layer 310; and the third and fourth openings 473 and 474 may be formed to be directly above, thereby expose, the third and fourth TSVs 323 and 324 in the second device layer 310.

Next, as is illustrated in FIG. 2R, a third liner 480 may be formed on top of the first bonding layer 470 lining the first, second, third, and fourth openings 471, 472, 473, and 474 and sidewalls thereof. The third liner 480 may thus cover the first, second, third, and fourth TSVs 321, 322, 323, and 324. A layer of conductive material 489 such as, for example, Cu may be formed in the first, second, third, and fourth openings 471, 472, 473, and 474 and on top of the first bonding layer 470 through, for example, an electroplating process, a CVD process, a PVD process, or an ALD process. Next, as is illustrated in FIG. 2S, a CMP process may be applied to remove excess portions of the conductive material 489 on top of the first bonding layer 470 thereby forming a first, a second, a third and a fourth bonding pad 481, 482, 483, and 484.

In one embodiment, the first, second, third, and fourth bonding pads 481, 482, 483, and 484 may be slightly recessed, in the range of 1 nm to 10 nm, through a special CMP process for better bonding process and resulting quality.

Hereby, a second semiconductor build 20 is prepared and hybrid bonded with the first semiconductor build 10. Similar to the first semiconductor build 10, the second semiconductor build 20 may include the second device layer 310, the second dielectric layer 410, and the passivation layer 440 to have an overall thickness ranging from about 10 μm to about 120 μm. The first and second semiconductor builds 10 and 20 are now ready to be hybrid bonded to one or more semiconductor builds. Manufacturing and bonding of the one or more semiconductor builds may be similar to what is described above with regard to the first semiconductor build 10 and/or the second semiconductor build 20, and whose description may thus be omitted herein.

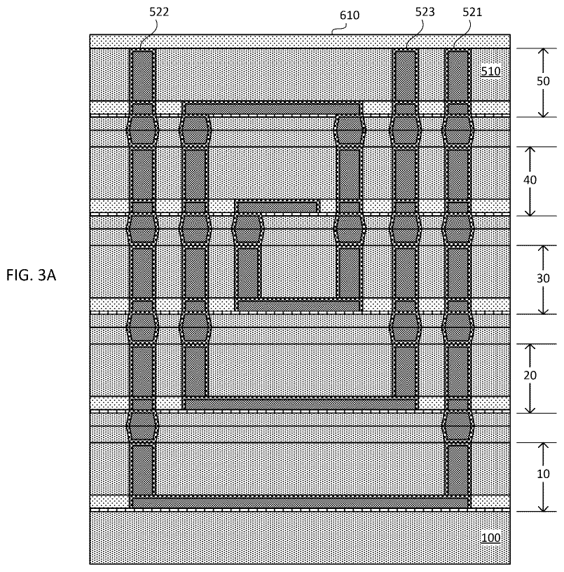

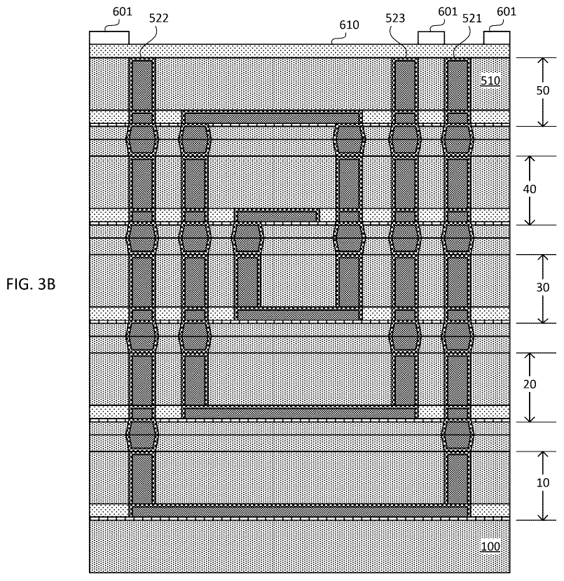

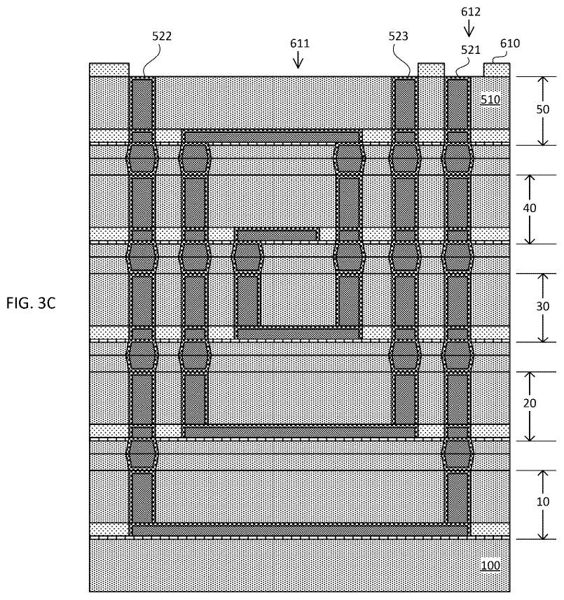

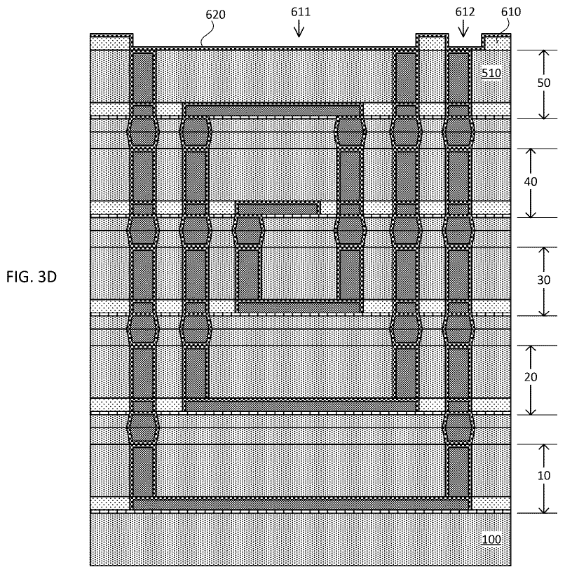

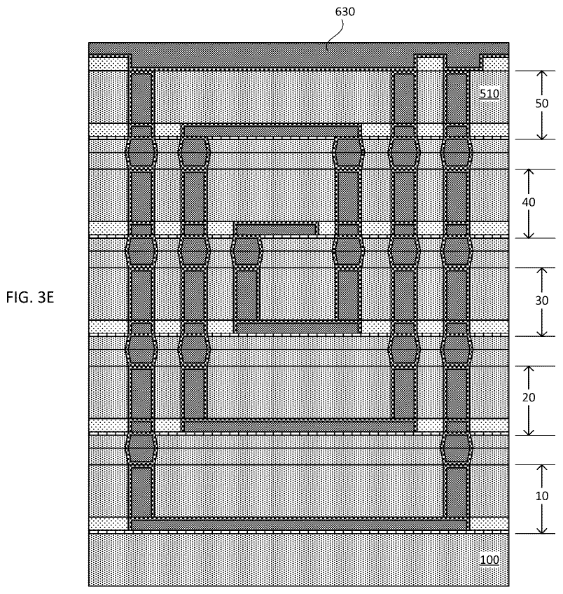

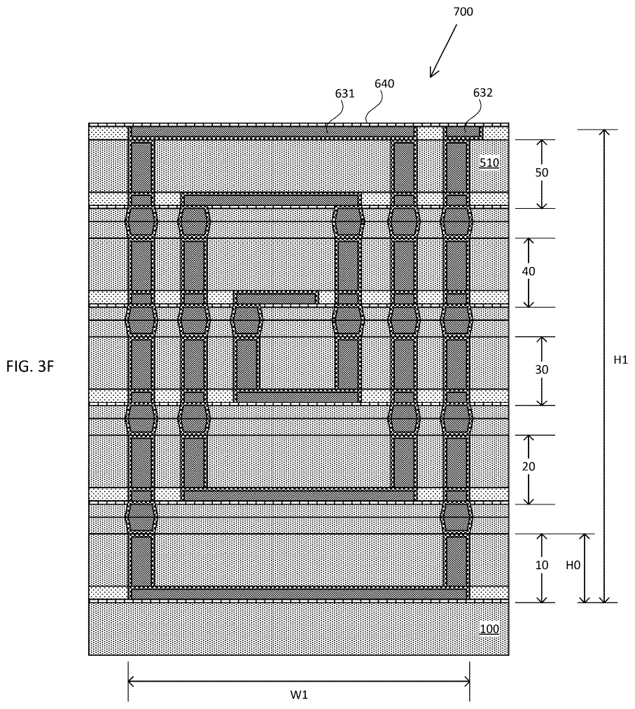

FIG. 3A to FIG. 3F are demonstrative illustrations of cross-sectional views of additional semiconductor builds and their hybrid bonding with the first and second semiconductor builds, in a process of manufacturing thereof, that forms the inductor in a bonded integrated circuit assembly according to one embodiment of present invention. More particularly, embodiments of present invention continue to form a third semiconductor build 30 on top of and hybrid bonded to the second semiconductor build 20, a fourth semiconductor build 40 on top of and hybrid bonded to the third semiconductor build 30, and a fifth semiconductor build 50 on top of and hybrid bonded to the fourth semiconductor build 40, in processes or manners substantially similar to forming the first and/or the second semiconductor builds 10 and 20, and the hybrid bonding may be made through a pair of bonding layers with two or more sets of bonding pads. Here it is to be noted that embodiments of present invention are not limited in this aspect and a plurality of semiconductor builds, more or less than five semiconductor builds as being illustrated in FIG. 3A, may be used or formed.

In addition, each of the semiconductor builds may include two or more TSVs that are vertically aligned respectively with two or more TSVs of an adjacent one of the semiconductor builds. Each of the semiconductor builds may include a horizontal bar, and the plurality of horizontal bars may conductively connect to one or two of the two or more TSVs of the plurality of semiconductor builds. Moreover, the two or more TSVs of each of the semiconductor builds and the plurality of horizontal bars may be concatenated together, except in the top semiconductor build wherein a horizontal bar is to be formed hereinafter, to form an inductor that has a spiral shape, in a vertical plane, and spans across the plurality of semiconductor builds.

As is illustrated in FIG. 3A, after forming the top semiconductor build such as the fifth semiconductor build 50, embodiments of present invention provide forming a dielectric layer 610 on top of the fifth semiconductor build 50 and more particularly on top of a fifth device layer 510 of the fifth semiconductor build 50. Next, embodiments of present invention provide forming a horizontal bar in the dielectric layer 610. The fifth semiconductor build 50 includes three TSVs such as a first, a second, and a third TSV 521, 522, and 523 and the horizontal bar may be formed to conductively connect the second and third TSVs 522 and 523 in the fifth semiconductor build 50. For example, as is illustrated in FIG. 3B, embodiments of present invention provide forming a photomask 601 on top of the dielectric layer 610 with two openings that are directly above the first, second, and third TSVs 521, 522, and 523 and above the region between the second and third TSVs 522 and 523.

Next, as is illustrated in FIG. 3C, embodiments of present invention provide transferring the openings onto the dielectric layer 610 to create a first opening 611 that exposes the second and third TSVs 522 and 523 in the fifth semiconductor build 50 and a second opening 612 that exposes the first TSV 521 in the fifth semiconductor build 50. Next, as is illustrated in FIG. 3D, embodiments of present invention provide forming a liner 620 on top of top surfaces of the first, second, and third TSVs 521, 522, and 523, top surface of the fifth device layer 510, and sidewalls of the first and second openings 611 and 612. Next, as is illustrated in FIG. 3E, embodiments of present invention provide performing metallization of the first and second openings 611 and 612 by forming a conductive material 630, such as Cu, in the first and second openings 611 and 612. Next, as is illustrated in FIG. 3F, embodiments of present invention provide applying a CMP process to remove excess portions of the conductive material 630 on top of the dielectric layer 610. The CMP process may also remove portions of the liner 620 on top of the dielectric layer 610 as well. The CMP process may thereby produce a horizontal bar 631 that conductively connects the second and third TSVs 522 and 523 and a conductive stud or pad 632 that is in contact with the first TSV 521. The conductive pad 632 may form a part of a contact terminal, such as a second terminal, of an inductor 700.

As is demonstratively illustrated in FIG. 3F, the two or more TSVs of each of the semiconductor builds 10, 20, 30, 40, and 50 and the plurality of horizontal bars, including the horizontal bar 631 above the fifth semiconductor build 50, are concatenated together to form the inductor 700. The inductor 700 has a vertically oriented spiral shape, in other words has a spiral shape in a vertical plane that spans across the plurality of semiconductor builds 10, 20, 30, 40, and 50. Each of the semiconductor builds 10, 20, 30, 40, and 50 may have a thickness H0 ranging from about 10 μm to about 120 μm.

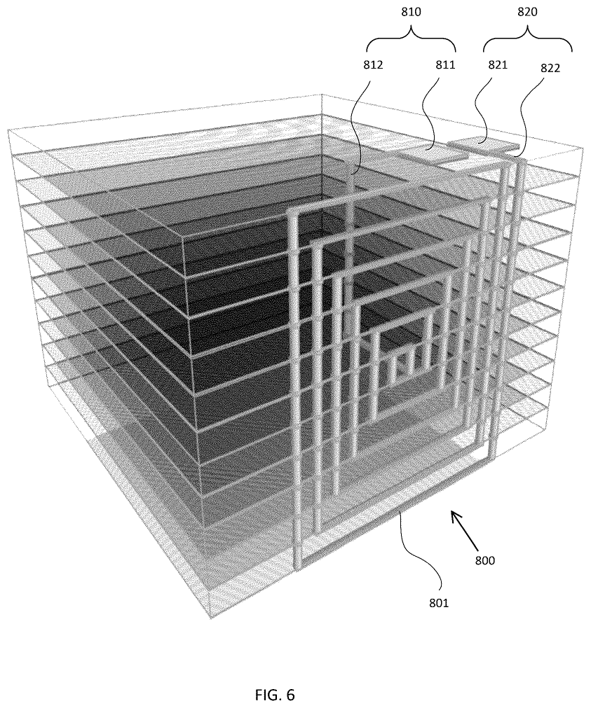

Here, it is to be noted that during the manufacturing of the various semiconductor builds and their bonding in forming the integrated circuit assembly, additional TSVs may be formed in a vertical plane, and this vertical plane may be away from the vertical plane of the vertically oriented spiral shape of the inductor 700. These additional TSVs may be substantially vertically aligned to form a part of a contact terminal, such as a first terminal of the inductor 700, as is demonstratively illustrated in FIG. 6.

As is demonstratively illustrated in FIG. 3F, the spiral shape of the inductor 700 has both horizontal and vertical sides and thus is a rectangular spiral shape. The inductor 700 may have a horizontal width W1 ranging from about 1000 μm to about 30000 μm, and a vertical height H1 ranging from about 40 μm to about 800 μm.

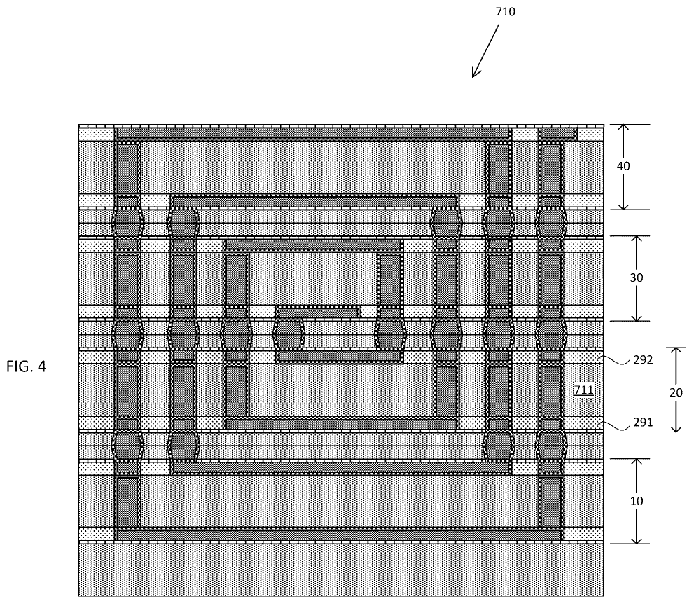

FIG. 4 is a demonstrative illustration of cross-sectional view of an inductor 710 in a bonded integrated circuit assembly according to another embodiment of present invention. Like the inductor 700 as is illustrated in FIG. 3F, the inductor 710 includes multiple semiconductor builds 10, 20, 30, and 40 that are bonded together through multiple sets of bonding pads in multiple pairs of bonding layers. Unlike the inductor 700, one or more of the semiconductor builds 10, 20, 30, and 40 in the inductor 710 may include two dielectric layers. For example, the semiconductor build 20 may include a first dielectric layer 291 and a second dielectric layer 292, at both a top and a bottom of a device layer 711. The two dielectric layers 291 and 292 may each include a horizontal bar that form part of the spiral shape of the inductor 710. For example, the horizontal bar in the dielectric layer 291 may be conductively connected to two of the TSCV's in the semiconductor build 20, and the horizontal bar in the dielectric layer 292 may be conductively connected to two bonding pads.

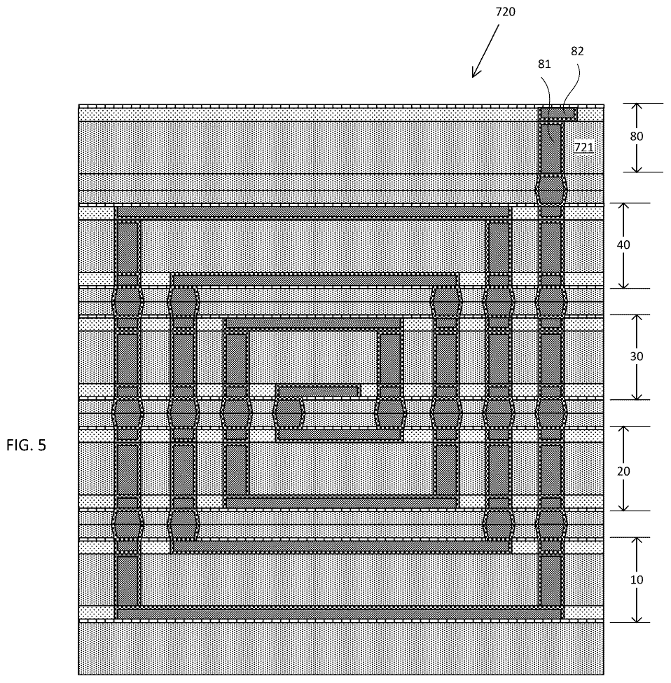

FIG. 5 is a demonstrative illustration of cross-sectional view of an inductor 720 in a bonded integrated circuit assembly according to yet another embodiment of present invention. Like the inductor 700 illustrated in FIG. 3F and the inductor 710 illustrated in FIG. 4, the inductor 720 includes multiple semiconductor builds 10, 20, 30, and 40 that are bonded together through multiple sets of bonding pads in multiple pairs of bonding layers. Unlike the inductor 700, the inductor 720 may include an additional semiconductor build, such as a semiconductor build 80, bonded to the top semiconductor build 40 of the spiral shape of the inductor 720. The semiconductor build 80 may include a TSV 81 in a device layer 721 that is vertically aligned with, and conductively connected to, a TSV at an outer end of the spiral shape. In addition, a contact terminal or contact pad 82 may be formed in a dielectric layer above the device layer 721, making conductive contact with the TSV 81.

FIG. 6 is a perspective view of an inductor in integrated circuit according to a further embodiment of present invention. More particularly, embodiments of present invention provide an inductor 800 in a bonded integrated circuit assembly. The inductor 800 includes a concatenated TSVs and horizontal bars in a spiral shape 801. The spiral shape 801 stays within a vertical plane to be vertically oriented. The inductor 800 may include a first contact terminal 810 that includes a first contact pad 811 and a first contact lead 812. The first contact lead 812 may be formed from multiple vertically aligned TSVs and have a first horizontal bar leading to the first contact pad 811 and a second horizontal bar leading to a first end (i.e., an inner end) of the spiral shape 801 of the inductor 800 at a center thereof. The inductor 800 may also include a second contact terminal 820 that includes a second contact pad 821 and a second contact lead 822. The second contact lead 822 may be in contact with a second end (i.e., an outer end) of the spiral shape 801 at an edge thereof.

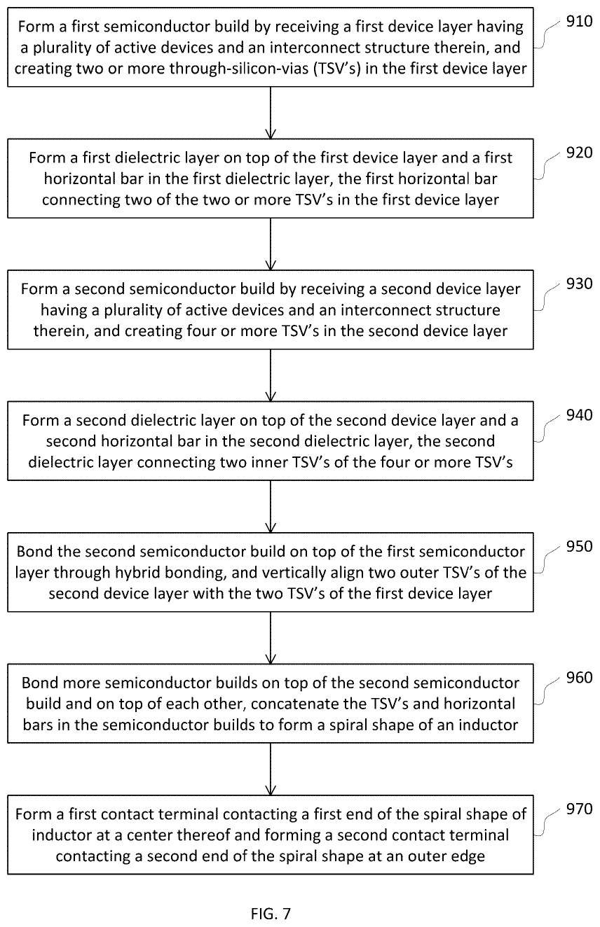

FIG. 7 is a demonstrative illustration of a flow-chart of a method of manufacturing a semiconductor structure according to embodiments of present invention. The method includes (910) forming a first semiconductor build by receiving a first device layer having a plurality of active devices and an interconnect structure therein, and creating two or more through-silicon-vias (TSVs) in the first device layer; (920) forming a first dielectric layer on top of the first device layer and a first horizontal bar in the first dielectric layer thereby forming the first semiconductor build, where the first horizontal bar connects two of the two or more TSVs in the first device layer; (930) forming a second semiconductor build by receiving a second device layer having a plurality of active devices and an interconnect structure therein, and creating four or more TSVs in the second device layer; (940) forming a second dielectric layer on top of the second device layer and a second horizontal bar in the second dielectric layer thereby forming the second semiconductor build, where the second dielectric layer connects two inner TSVs of the four or more TSVs; (950) bonding the second semiconductor build on top of the first semiconductor build through hybrid bonding, and vertically aligning two outer TSVs of the second device layer with the two TSVs of the first device layer; (960) bonding more semiconductor builds on top of the second semiconductor build and on top of each other, and concatenating the multiple TSVs and horizontal bars in the semiconductor builds to form a spiral shape of an inductor; and (970) forming a first contact terminal contacting a first end of the spiral shape of the inductor at a center thereof and forming a second contact terminal contacting a second end of the spiral shape at an outer edge of the inductor.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising an inductor, the inductor comprising:
a plurality of semiconductor builds bonded together with one on top of another, each of the plurality of semiconductor builds having two or more through-silicon vias (TSVs) that are vertically aligned with two or more TSVs of an adjacent semiconductor build of the plurality of semiconductor builds; and
a plurality of horizontal bars conductively connecting two of the two or more TSVs of each of the plurality of semiconductor builds,
wherein the two or more TSVs of each of the plurality of semiconductor builds and the plurality of horizontal bars are concatenated together to have a spiral shape in a vertical plane, the spiral shape spanning across the plurality of semiconductor builds.

2. The semiconductor structure of claim 1, wherein each of the plurality of semiconductor builds contains a device layer, and the device layer includes a plurality of front-end-of-line devices and a back-end-of-line interconnect structure.

3. The semiconductor structure of claim 2, wherein each of the plurality of semiconductor builds contains at least one dielectric layer at one side of the device layer, and the dielectric layer has at least one of the plurality of horizontal bars embedded therein.

4. The semiconductor structure of claim 3, wherein each of the plurality of semiconductor builds contains a passivation layer, the passivation layer directly adjacent to the at least one of the plurality of horizontal bars.

5. The semiconductor structure of claim 1, wherein each of the plurality of semiconductor builds has a thickness ranging from about 10 μm to about 120 μm.

6. The semiconductor structure of claim 1, wherein the spiral shape in the vertical plane is a rectangular spiral shape with a horizontal width ranging from about 1000 μm to about 30000 μm, and a vertical height ranging from about 40 μm to about 800 μm.

7. The semiconductor structure of claim 1, further includes a first contact lead and a second contact lead, the first contact lead being in contact with an outer end of the spiral shape of the inductor.

8. The semiconductor structure of claim 7, wherein the second contact lead is in another vertical plane away from the vertical plane of the spiral shape of the inductor and is in contact with an inner end of the spiral shape of the inductor via another horizontal bar.

9. The semiconductor structure of claim 1, wherein there is a pair of bonding layers with at least one set of bonding pads between any two of the plurality of semiconductor builds.

10. The semiconductor structure of claim 9, wherein the inductor is bonded to a supporting structure.

11. A method of forming a semiconductor structure comprising:
forming a first semiconductor build with two through-silicon vias (TSVs) embedded therein and a first horizontal bar connecting the two TSVs;
forming a second semiconductor build with four TSVs embedded therein and a second horizontal bar connecting two inner TSVs of the four TSVs; and
bonding the second semiconductor build to the first semiconductor build with the second horizontal bar facing the first semiconductor build, wherein two outer TSVs of the four TSVs of the second semiconductor build are vertically aligned with and bonded to the two TSVs of the first semiconductor build through two pairs of bonding pads.

12. The method of claim 11, further comprising forming one or more additional semiconductor builds that are bonded together and bonded on top of the second semiconductor build, the one or more additional semiconductor builds each includes two or more TSVs and one or more horizontal bars with each horizontal bar connecting two of the two or more TSVs, wherein the TSVs and the horizontal bars in the first, the second, and the one or more additional semiconductor builds are concatenated together to form an inductor with a spiral shape in a vertical plane.

13. The method of claim 12, further comprising forming a first and a second contact lead, the second contact lead having two or more vertically concatenated TSVs formed in another vertical plane away from the vertical plane of the spiral shape of the inductor.

14. The method of claim 11, wherein forming the first semiconductor build comprises:
receiving a first device layer, the first device layer having a plurality of front-end-of-line devices and a back-end-of-line interconnect structure;
creating the two TSVs in the first device layer;
forming a first dielectric layer on top of the first device layer; and
forming the first horizontal bar in the first dielectric layer, the first horizontal bar connecting the two TSVs in the first device layer.

15. The method of claim 11, wherein forming the second semiconductor build comprises:
receiving a second device layer, the second device layer having a plurality of front-end-of-line devices and a back-end-of-line interconnect structure;
creating the four TSVs in the second device layer;
forming a second dielectric layer on top of the second device layer; and
forming the second horizontal bar in the second dielectric layer, the second horizontal bar connecting the two inner TSVs of the four TSVs in the second device layer.

16. An inductor comprising:
multiple semiconductor builds bonded together with one on top of another, each of the multiple semiconductor builds having two or more through-silicon vias (TSVs) that are vertically aligned with two or more TSVs of an adjacent one of the multiple semiconductor builds; and
multiple horizontal bars embedded in each of the multiple semiconductor builds, the multiple horizontal bars conductively connecting one or two of the two or more TSVs of the multiple semiconductor builds,
wherein the two or more TSVs of each of the multiple semiconductor builds and the multiple horizontal bars are concatenated together, having a spiral shape in a vertical plane that spans across the multiple semiconductor builds.

17. The inductor of claim 16, wherein each of the multiple semiconductor builds contains a device layer, the device layer including a plurality of front-end-of-line devices and a back-end-of-line interconnect structure; and contains a dielectric layer at a top or a bottom of the device layer, the dielectric layer including one of the multiple horizontal bars.

18. The inductor of claim 16, wherein the spiral shape is a rectangular spiral shape with a horizontal width ranging from about 1000 μm to about 30000 μm, and a vertical height ranging from about 40 μm to about 800 μm.

19. The inductor of claim 18, further includes a contact lead, the contact lead being in contact with an outer end of the spiral shape of the inductor.

20. The inductor of claim 16, wherein between each of the multiple semiconductor builds is a pair of bonding layers, the pair of bonding layers having two or more sets of bonding pads.
